(19) United States
(12) Patent Application Publication
(10) Pub. No.: US 2022/0328761 A1
(43) Pub. Date: Oct. 13, 2022

(54) PHASE CHANGE MATERIAL, PHASE CHANGE MEMORY CELL AND PREPARATION METHOD THEREFOR

(71) Applicant: SHANGHAI INSTITUTE OF MICROSYSTEM AND INFORMATION TECHNOLOGY, CHINESE ACADEMY OF SCIENCES, Shanghai (CN)

(72) Inventors: Sannian SONG, Shanghai (CN); Yuan XUE, Shanghai (CN); Zhitang SONG, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 17/605,584

(22) PCT Filed: May 22, 2019
(86) PCT No.: PCT/CN2019/087889

§ 371 Date: Mar. 2, 2022

(30) Foreign Application Priority Data
Apr. 23, 2019 (CN) 201910329526.7

(51) Int. Cl. H01L 45/00

(52) U.S. Cl. CPC H01L 45/144; H01L 45/06; H01L 45/1616; H01L 45/1625

(57) ABSTRACT

A phase change material, a phase change memory cell, and a preparation method thereof. The phase change material comprises elements tantalum, antimony and tellurium, the phase change material having a chemical formula of TaₓSb_{y}Te_{z}, wherein x, y, and z represent atomic ratios of the elements respectively; and 1≤x≤25, 0.5≤y:z≤3, and x+y+z=100. The phase change thin film material TaₓSb_{y}Te_{z} has a high phase change speed, outstanding thermal stability, strong data retention capability, a long cycle life, and a high yield. Ta_{5.7}Sb_{37.7}Te_{56.6} has ten-year data retention capability at 165° C.; and applying same in a device cell of a phase change memory achieves an operating speed of 6 ns and endurance of more than 1 million write-erase cycles. The crystal grains of the phase change material TaₓSb_{y}Te_{z} of the present disclosure are small, and after annealing treatment at 400° C. for 30 minutes, the grain size is still smaller than 30 nm.

### CROSS REFERENCE TO RELATED APPLICATION

This is a Sect. 371 National Stage of PCT International Application No. PCT/CN2019/087889, filed on May 22, 2019, which claims the benefit of priority to Chinese Patent Application No. CN 2019103295267, entitled “PHASE CHANGE MATERIAL, PHASE CHANGE MEMORY CELL AND PREPARATION METHOD THEREOF”, filed with CNIPA on Apr. 23, 2019, the disclosure of which is incorporated herein by reference in its entirety.

### FIELD OF TECHNOLOGY

The present disclosure generally relates to microelectronics technology, in particular, to a phase change material, a phase change memory cell, and a preparation method thereof.

### BACKGROUND

Phase change memory (PCM) is a non-volatile semiconductor memory that has been developed rapidly in recent years. Compared with traditional memory, it has the advantages of non-volatility, good microscopicity, fast read/write speed, low power consumption, long cycle life, and excellent anti-irradiation performance. Therefore, phase change memory has become the strongest competitor among various new storage technologies and is expected to become the mainstream storage technology for next-generation non-volatile memory. At present, it is expected to be applied in new fields such as storage class memory because its performance such as speed and cycle life is between flash memory and dynamic random memory (DRAM).

The key to the application of phase change memory is its change material, which is capable of reversible conversion between high and low resistance under the influence of electrical pulse signals, in order to store “0” and “1”. Specifically, the phase change material has a high resistance value in an amorphous state and a low resistance value in a crystalline state. The performance of the phase change material determines the performance of the phase change memory. The most typical phase change material at present is Ge₂Sb₂Te₅, which has characteristics such as a long cycle life and good microscopicity, and has been widely used in phase change discs and phase change memories. However, Ge₂Sb₂Te₅ still has some problems: (1) It has low thermal stability. The operating temperature of Ge₂Sb₂Te₅ for ten-year reliable data storage is only about 80° C., so it cannot be applied in high-temperature enviorment such as automotive electronics and aerospace. (2) It has low crystallization temperature. Due to its crystallization temperature of around 150° C., it cannot withstand a reflow soldering process of about 260° C. in embedded packaging, thereby risking data loss, and therefore it cannot be applied in embedded memory. (3) It cannot withstand high temperature processes in later stages of the CMOS process, which tends to cause phase splitting or formation of holes, leading to device failure. (4) Its phase change speed is slow. Currently, the write speed of a phase change memory based on Ge₂Sb₂Te₅ is only in the order of 100 nanoseconds, which is not enough for it to replace DRAMs.

To solve above problems, new phase change materials such as Si-Sb-Te, Al-Sb-Te, Ti-Sb-Te, and Sc-Sb-Te have been developed in recent years. However, it was found that these materials cannot achieve high speed phase change and good thermal stability at the same time. These new phase change materials also have problems in engineering: (1) Ti-Sb-Te and Sc-Sb-Te have advantages in speed and power consumption, but are limited in data retention capability, and cannot meet the demand for data retention capability in fields such as automotive electronics and aerospace. (2) Although Si-Sb-Te and Al-Sb-Te achieve significant improvement in thermal stability and data retention capability, phase splitting of these materials makes it difficult to improve the cycle life of the resulting devices. (3) These materials show obvious grain growth after a high temperature process at 400° C., which leads to element segregation and phase splitting, resulting in increased power consumption and deterioration of device performance. (4) The four elements Si, Al, Ta, and Sc are very prone to oxidization, especially Sc, which is susceptible to oxidation in the process, leading to a lower device speed, discrete inter-cell resistance distribution, degraded electrical properties, and a lower yield.

Therefore, seeking a phase change thin film material with a fast phase change speed, high thermal stability, long cycle life, strong data retention capability, high yield and compatibility with the CMOS process has become an important technical problem to be solved by those skilled in the art.

### SUMMARY

The present disclosure provides a phase change material. The phase change material includes elements tantalum, antimony and tellurium, and the phase change material has a chemical formula of TaₓSb_{y}Te_{z}, wherein x, y, and z represent atomic ratios of the elements, respectively; and 1≤x≤25, 0.5≤y:z≤3, and x+y+z=100.

Optionally, in TaₓSb_{y}Te_{z}, 2x10, 25≤y≤45, and 40≤z≤70.

Optionally, in TaₓSb_{y}Te_{z} 3.5≤x≤9, 30≤y≤40, and 50≤z≤60.

Optionally, in TaₓSb_{y}Te_{z} 4≤x≤8, 36≤y≤39.6, and 54≤z≤59.4.

Optionally, the phase change material has an average grain size of less than 30 nm after annealing treatment at 400° C. for 30 minutes.

The present disclosure also provides a phase change memory cell, including:
a bottom electrode layer;
a top electrode layer; and
a phase change material layer between the bottom electrode layer and the top electrode layer, the phase change material layer including the phase change material of any embodiments described above.

Optionally, the phase change material layer has a thickness ranging from 20 nm to 150 nm.

The present disclosure also provides a preparation method for a phase change memory cell, including the following steps:

preparing a bottom electrode layer;

preparing a phase change material layer on the bottom electrode layer, the phase change material layer including the phase change material of any embodiments described above; and

preparing a top electrode layer on the phase change material layer.

Optionally, the phase change material layer is prepared by any one of magnetron sputtering, chemical vapor deposition, atomic layer deposition, and electron beam evaporation.

Optionally, the phase change material is prepared by co-sputtering with a monolithic target or by sputtering with an alloy target.

As described above, the phase change thin film material TaₓSb_{y}Te, of the present disclosure has the characteristics of a high phase change speed, outstanding thermal stability, strong data retention capability, long cycle life, and high yield, and storage materials with different crystallization temperatures, resistivity and crystallization activation energy can be obtained by adjusting the contents of the three elements. Thus, the phase change material TaₓSb_{y}Te_{z} is highly adjustable, which is conducive to the optimization of various properties of the phase change material. Ta₆₇Sb₃₇₇⁻1e₆₆₆has ten-year data retention capability at 165° C., and applying Ta_{6 7}Sb₃₇₇⁻1e_{66 6} in a device cell of a phase change memory can achieve an operating speed of 6 ns and endurance of more than 1 million write-erase cycles. Moreover, the crystal grains of the phase change material TaₓSb_{y}Te_{z} of the present disclosure are very small, and after annealing treatment at 400° C. for 30 minutes, the grain size is still smaller than 30 nm, which is an important factor for stability, low power consumption, and yield of a device. The preparation method for a phase change memory cell of the present disclosure is compatible with CMOS processes, and facilitates accurate control of the composition of the phase change material.

### BRIEF DESCRIPTION OF THE DRAWINGS

FIG. 1 is a graph showing resistance-temperature relationships of Sb₂Te₃ and phase change materials TaₓSb_{y}Te_{z} with different components provided in the present disclosure.

FIG. 2 is a graph showing calculated results of data retention capabilities of phase change materials TaₓSb_{y}Te_{z} with different components provided in the present disclosure.

FIG. 3 is a graph showing resistance-voltage relationships of a phase change memory cell adopting phase change material Ta_{5.7}Sb_{37.7}Te_{56.6}.

FIG. 4 is a graph showing fatigue performance of a phase change memory cell adopting phase change material Ta_{5.7}Sb_{37.7}Te_{56.6}.

### DETAILED DESCRIPTION

Embodiments of the present disclosure will be described below with specific examples, and other advantages and effects of the present disclosure may be easily understood by those skilled in the art from the disclosure in the specification. The present disclosure may also be carried out or applied in other different specific embodiments, and various modifications or changes may also be made to the details in the specification based on different ideas and applications without departing from the spirit of the present disclosure.

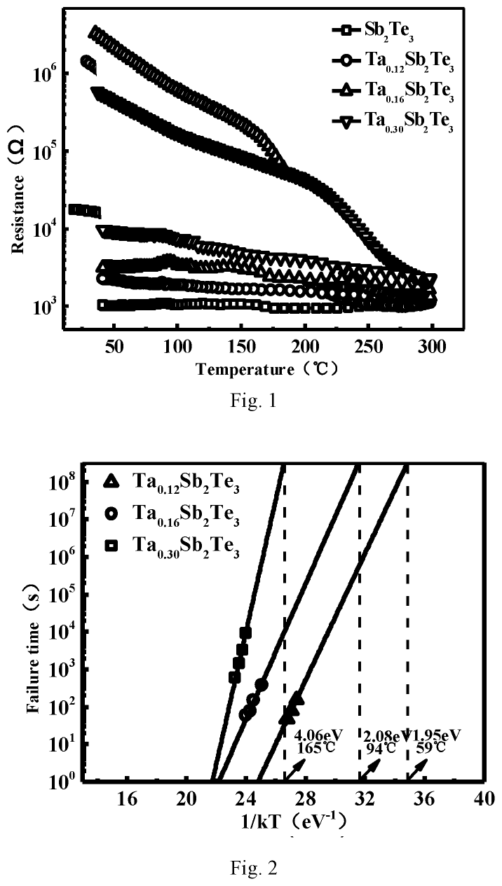

Please refer to FIGS. 1 to 4. It is to be noted that drawings provided in the embodiments only schematically illustrate the basic idea of the present disclosure, so the drawings only show components related to the present disclosure, and are not drawn according to the numbers, shapes and sizes of the components in actual implementation; the forms, numbers and proportions of the components in actual implementation may be varied as needed; and the layout of the components may be more complex.

### Embodiment 1

This embodiment provides a phase change material. The phase change material includes elements tantalum (Ta), antimony (Sb) and tellurium (Te), and the phase change material has a chemical formula of TaₓSb_{y}Te_{z}, wherein x, y, and z represent atomic ratios of the elements, respectively; and 1≤x≤25, 0.5≤y:z≤3, and x+y+z=100.

Specifically, the contents of the three elements in TaₓSb_{y}Te_{z} can be adjusted to obtain storage materials with different crystallization temperatures, resistivity and crystallization activation energy. For example, the formula TaₓSb_{y}Te_{z} may further satisfy conditions 2≤x≤10, 25≤y≤45, and 40≤z≤70, or further satisfy conditions 3.5≤x≤9, 30≤y≤40, and 50≤z≤60, or further satisfy conditions 4≤x≤8, 36≤y≤39.6, and 54≤z≤59.4. In this embodiment, x, y, and z preferably satisfy conditions x=5.7, y=37.7, and z=56.6, i.e., the chemical formula of the phase change material is Ta_{5.7}Sb_{37.7}Te_{56. 6}.

Specifically, the phase change material TaₓSb_{y}Te_{z} has at least two stable resistance states under the action of electrical pulse signals, is capable of reversible conversion between high and low resistance under the operation of electrical pulse signals, and its resistance value remains unchanged when there is no electrical pulse signal present.

Specifically, the phase change material TaₓSb_{y}Te_{z} have ten-year data retention capabilities at a temperature over 150° C., an operating speed of high than 6 ns, and a cycle life of more than 10⁶ cycles.

Specifically, the crystal grains of the phase change material TaₓSb_{y}Te_{z} are very small, and after annealing treatment at 400° C. for 30 minutes, its average grain size is still smaller than 30 nm, which is very important for the stability, low power consumption, and yield of a memory device.

Specifically, the phase change material TaₓSb_{y}Te_{z} may be in the form of a thin film. As an example, the phase change material TaₓSb_{y}Te_{z} has a film thickness ranging from 20 nm to 150 nm. For example, the thickness of the phase change material TaₓSb_{y}Te_{z} may be 30 nm, 50 nm, 60 nm, 80 nm, 100 nm, 120 nm, 140 nm, 150 nm, or the like. In this embodiment, the film thickness of the phase change material TaₓSb_{y}Te_{z} is preferably 60 nm.

FIG. 1 shows a graph of resistance-temperature relationships of Sb₂Te₃ and phase change materials TaₓSb_{y}Te_{z} with different components provided in the present disclosure. The chemical formulas of the phase change materials TaₓSb_{y}Te_{z} are Ta_{2.3}Sb_{39.1}Te_{58.6}, Ta_{3.1}Sb_{38.8}Te_{58.1}, and Ta_{5.7}Sb_{37.7}Te_{56.6}, respectively (equivalent to Ta_{0.12}Sb₂Te₃, Ta_{0.16}Sb₂Te₃, and Ta_{0.30}Sb₂Te₃, respectively). As can be seen from FIG. 1, the crystallization temperature of the phase change material TaₓSb_{y}Te_{z} can be adjusted between 150° C. and 250° C., which is a substantial increase compared to that of Sb₂Te₃ (about 70° C.). In addition, the crystallization temperature of the phase change material TaₓSb_{y}Te_{z} of the present disclosure is also obviously increased compared to that of the conventional Ge₂Sb₂Te₅ (about 150° C.). Moreover, the high resistance of TaₓSb_{y}Te_{z} increases and then decreases with increase of the tantalum content, and its crystallization temperature increases with increase of the tantalum content. Therefore, the crystallization temperature of the phase change material TaₓSb_{y}Te_{z} may be controlled by adjusting the tantalum content.

Please refer to FIG. 2, which shows a graph of calculation results of data retention capabilities of the phase change materials TaₓSb_{y}Te_{z} with different components provided in the present disclosure. The chemical formulas of the phase change materials TaₓSb_{y}Te_{z} are Ta_{2.3}Sb_{39.1}Te_{58.6}, Ta_{3.1}Sb_{38.8}Te_{58.1}, and Ta_{5.7}Sb_{37.7}Te_{56.6}, respectively (equivalent to Ta_{0.12}Sb₂Te₃, Ta_{0.16}Sb₂Te₃, and Ta_{0.30}Sb₂Te₃, respectively). As can be seen from FIG. 2, the 10-year data retention temperature of the phase change material TaₓSb_{y}Te_{z} increases with the increase of its tantalum content. Furthermore, it can be seen that the 10-year data retention capability of the phase change material TaₓSb_{y}Te_{z} is improved compared to that of Ge₂Sb₂Te₅ when the tantalum content exceeds 3.1%. Therefore, the thermal stability and data retention capability of the phase change material TaₓSb_{y}Te_{z} may be optimized by adjusting the tantalum content.

The phase change thin film material TaₓSb_{y}Te_{z} of the present disclosure has characteristics such as high phase change speed, outstanding thermal stability, strong data retention capability, long cycle life, and high yield, mainly for the following reasons: (1) the element tantalum is a common material for semiconductors and is compatible with COMS processes; (2) the atomic weight of the element tantalum (Ta) (180.947 g/mol) is much larger than that of the elements germanium (Ge) (72.59 g/mol), titanium (Ti) (47.90 g/mol), scandium (Sc) (44.95 g/mol) and the like, which means that Ta atoms diffuse more slowly in the phase change material and can function to inhibit grain growth and improve thermal stability, and increase the crystallization temperature and improve the ten-year data retention capability of the phase change material, which is especially important for engineering; (3) the thermal conductivity coefficient of Ta (57.5 J/m-sec-deg) is lower than that of Ge (60.2 J/m-sec-deg), and the overall thermal conductivity of the film is reduced due to the small grain size and increased grain boundaries, so PCM devices using Ta-doped Sb-Te-based phase change materials are expected to have relatively low operational power consumption; (4) the atomic radius of Ta (146 pm) is close to that of Sb (140 pm), and there exists a stable compound TaTe₂ composed of Ta and Te, resulting in a possibility that Sb atoms are replaced after Sb-Te are doped with Ta atoms, thus forming a stable structure which promotes the crystallization of the Sb-Te-based phase change material, so high-speed phase change is expected to be achieved; and (5) the element Ta is chemically stable and does not react with oxygen and water in the air, and can reduce the damage of oxidation to device performance in the process, which is conducive to the improvement of the device yield.

### Embodiment 2

This embodiment provides a phase change memory cell. The phase change memory cell includes a bottom electrode, a top electrode, and a phase change material layer between the bottom electrode layer and the top electrode layer. The phase change material layer includes the phase change material TaₓSb_{y}Te_{z} of Embodiment 1. That is, the phase change material includes elements tantalum (Ta), antimony (Sb) and tellurium (Te), and the phase change material has a chemical formula of TaₓSb_{y}Te_{z}, wherein x, y, and z represent atomic ratios of the elements, respectively; and 0.5≤y:z≤3, and x+y+z=100.

As an example, the phase change material layer has a thickness ranging from 20 nm to 150 nm.

As an example, on the top electrode layer, a leading-out electrode is formed, through which the top electrode layer and the bottom electrode layer may be integrated with a control switch, drive circuit, and peripheral circuit of the device cell.

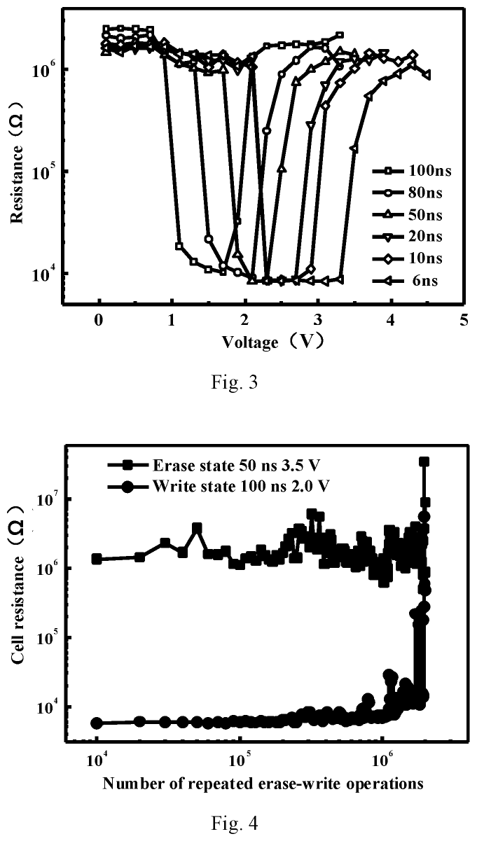

Refer to FIG. 3, which shows a graph of resistance-voltage relationship for a phase change memory cell adopting a phase change material Ta_{5.7}Sb_{37.7}Te_{56.6}. As seen in FIG. 3, the phase change memory cell can achieve a reversible phase change under the action of electrical pulses. In this embodiment, durations of voltage pulses for testing are 100, 80, 50, 20, 10, and 6 nanoseconds. It is to be noted that the memory cell device made of the phase change material TaₓSb_{y}Te_{z} can achieve “erase/write ” operations under an electrical pulse of as short as 6 nanoseconds, and “erase” and “write” operating voltages of the cell device are 4V and 2.3V, respectively.

Please refer to FIG. 4, which shows a graph of fatigue performance of the phase change memory cell using the phase change material Ta_{5.7}Sb_{37.7}Te_{56.6}. As seen in FIG. 4, the device can endure repeated erase-write operations of 2.0×10⁶ times, and have stable resistance values at high and low resistance states, which ensures the reliability required of the device in application.

As can be seen from the above description, in the phase change memory cell of the present disclosure, the phase change material TaₓSb_{y}Te_{z} has at least two stable resistance states under the action of electrical pulses, is capable of reversible conversion between high and low resistance under the operation of electrical pulse signals, and its resistance value remains unchanged when there is no electrical pulse signal present. Ta_{5.7}Sb_{37.7}Te_{56.6} has ten-year data retention capability at 165° C., and the memory cell in the phase change memory using Ta_{5.7}Sb_{37.7}Te_{56.6} has an operating speed of 6 ns and endurance of more than 1 million write-erase cycles. In addition, the very small grain size of the phase change material TaₓSb_{y}Te_{z} results in more grain boundaries in the phase change material, which reduces the overall thermal conductivity of the phase change film, so a PCM device using the phase change material TaₓSb_{y}Te, has relatively low operational power consumption.

### Embodiment 3

This embodiment provides a preparation method of a phase change memory cell, including the following steps:
S1: preparing a bottom electrode layer;
S2: preparing a phase change material layer on the bottom electrode layer, the phase change material layer including the phase change material of Embodiment 1, i.e., the phase change material including elements tantalum (Ta), antimony (Sb) and tellurium (Te), and the phase change material having a chemical formula of TaₓSb_{y}Te_{z}, wherein x, y, and z represent atomic ratios of the elements, respectively; and 1≤x≤25, 0.5≤y:z≤3, and x+y+z=100; and
S3: preparing a top electrode layer on the phase change material layer.

As an example, the bottom electrode layer may be prepared by sputtering, evaporation, chemical vapor deposition (CVD), plasma enhanced chemical vapor deposition (PECVD), etc. The material of the bottom electrode layer includes: one of monometallic materials Tungsten (W), platinum (Pt), gold (Au), titanium (Ti), aluminum (Al), silver (Ag), copper (Cu), and nickel (Ni), or an alloy formed by two or more of the above-mentioned monometallic materials, or a nitride or oxide of the monometallic materials. In this embodiment, the material of the bottom electrode layer is preferably W.

As an example, the phase change material layer may be prepared by a process such as magnetron sputtering, chemical vapor deposition, atomic layer deposition or electron beam evaporation.

As an example, the phase change material is prepared by co-sputtering of a Ta monometallic target and an Sb₂Te₃ alloy target according to the chemical formula TaₓSb_{y}Te_{z} of the phase change material.

As an example, an radio frequency power supply is used in sputtering of the Ta monometallic target, and a direct current power supply is used in sputtering of the Sb₂Te₃ alloy target; the sputtering power of the Ta monometallic target ranges from 20 W to 40 W, and the sputtering power of the Sb₂Te₃ alloy target ranges from 10 W to 30 W; and the sputtering time ranges from 10 to 30 minutes. In this embodiment, optionally the power of the Ta monometallic target is 20 W, the power of the Sb₂Te₃ alloy target is 20 W, and the sputtering time is 20 minutes.

As an example, during the preparation of the phase change material by co-sputtering of the Ta monometallic target and the Sb₂Te₃ alloy target, the base pressure is less than 3.0×10⁻⁴ Pa, the sputtering gas contains argon, and the sputtering temperature includes room temperature.

As an example, by adjusting process conditions, the contents of the three elements in the phase change material TaₓSb_{y}Te, can be adjusted to obtain storage materials with different crystallization temperatures, resistivity and crystallization activation energy. For example, TaₓSb_{y}Te_{z} may further satisfy 2≤x≤10, 25≤y≤45, and 40≤z≤70, or further satisfy 3.5≤x≤9, 30≤y≤40, and 50≤z≤60, or further satisfy 4≤x≤8, 36≤y≤39.6, and 54≤z≤59.4. In this embodiment, the phase change material is preferably Ta_{5.7}Sb_{37.7}Te_{56.6}, which has the advantages of higher thermal stability, stronger data retention capability, and faster crystallization.

As an example, the phase change material may also be prepared by three-target co-sputtering of a Ta monometallic target, an Sb monometallic target, and a Te monometallic target.

As an example, the phase change material may also be prepared by single-target sputtering of an alloy containing the elements tantalum, antimony and tellurium. The ratio of the three elements tantalum, antimony and tellurium in the alloy target is pre-configured. The alloy target may be prepared by physically mixing and sintering raw materials of the elements, or by chemical synthesis. The process of single-target sputtering can make the sputtering process easier to control compared to multi-target sputtering.

As an example, the top electrode layer may be prepared by sputtering, evaporation, chemical vapor deposition, plasma enhanced chemical vapor deposition, etc. The material of the top electrode layer includes: one of monometallic materials W, Pt, Au, Ti, Al, Ag, Cu, Ni, and Ta, or an alloy material formed by two or more of the above-mentioned monometallic materials, or a nitride or oxide of the monometallic materials. In this embodiment, the material of the top electrode layer is preferably TiN.

As an example, the preparation method further includes a step of forming a leading-out electrode on the top electrode layer, the material of the leading-out electrode including any one of W, Pt, Au, Ti, Al, Ag, Cu, Ta and Ni, or an alloy material formed by two or more of W, Pt, Au, Ti, Al, Ag, Cu, Ta and Ni. In this embodiment, the material of the leading-out electrode is preferably Al.

The preparation method for a phase change memory cell of the present disclosure is compatible with CMOS processes, and allows flexible adjustment of the contents of the elements in the phase change material TaₓSb_{y}Te_{z}, to obtain storage materials with different crystallization temperatures, resistivity, and crystallization activation energy.

In summary, the phase change thin film material TaₓSb_{y}Te_{z} of the present disclosure has the characteristics of high phase change speed, outstanding thermal stability, strong data retention capability, long cycle life, and high yield, and storage materials with different crystallization temperatures, resistivity and crystallization activation energy can be obtained by adjusting the contents of the three elements. Thus, the phase change material TaₓSb_{y}Te_{z} is highly adjustable, which is conducive to the optimization of various properties of the phase change material. Ta_{5.7}Sb_{37.7}Te_{56.6} has ten-year data retention capability at 165° C., and applying the same in a device cell of a phase change memory achieves an operating speed of 6 ns and endurance of more than 1 million write-erase cycles. Moreover, the crystal grains of the phase change material TaₓSb_{y}Te_{z} of the present disclosure are very small, and after annealing treatment at 400° C. for 30 minutes, the grain size is still smaller than 30 nm, which is very important for the stability, low power consumption, and yield of a device. The preparation method of a phase change memory cell of the present disclosure is compatible with CMOS processes, to facilitates accurate control of the composition of the phase change material. Therefore, the present disclosure effectively overcomes various shortcomings of the prior art and has a high value for industrial use.

The above embodiments are merely illustrative of the principles of the present disclosure and effects thereof, and are not intended to limit the present disclosure. Any person skilled in the art can modify or change the above embodiments without departing from the spirit and scope of the present disclosure. Therefore, all equivalent modifications or changes made by those with general knowledge in the technical field without departing from the spirit and technical ideas disclosed in the present disclosure are still covered by the claims of the present disclosure.

1. A phase change material, comprising elements tantalum, antimony and tellurium, wherein the phase change material has a chemical formula of TaₓSb_{y}Te_{z}, wherein x, y, and z represent atomic ratios of the elements, respectively, wherein 1≤x≤25, 0.5≤y:z≤3, and x+y+z=100.

2. The phase change material according to claim 1, wherein the formula TaₓSb_{y}Te_{z} satisfies conditions 2≤x≤10, 25≤y≤45, and 40≤z≤70.

3. The phase change material according to claim 1, wherein the formula TaₓSb_{y}Te_{z} satisfies conditions 3.5≤x≤9, 30≤y≤40, and 50≤z≤60.

4. The phase change material according to claim 1, wherein the formula TaₓSb_{y}Te_{z} satisfies conditions 4≤x≤8, 36≤y≤39.6, and 54≤z≤59.4.

5. The phase change material according to claim 1, wherein the phase change material has an average grain size of less than 30 nm after annealing treatment at 400° C. for 30 minutes.

6. A phase change memory cell, comprising:
a bottom electrode layer;
a top electrode layer; and
a phase change material layer between the bottom electrode layer and the top electrode layer, the phase change material layer comprising the phase change material of claim 1.

7. The phase change memory cell according to claim 6, wherein the phase change material has a thickness ranging from 20 nm to 150 nm.

8. A preparation method for a phase change memory cell, comprising the following steps:
preparing a bottom electrode layer;
preparing a phase change material layer on the bottom electrode layer, the phase change material layer comprising the phase change material of claim 1; and
preparing a top electrode layer on the phase change material layer.

9. The preparation method for a phase change memory cell according to claim 8, wherein the phase change material layer is prepared by any one of magnetron sputtering, chemical vapor deposition, atomic layer deposition, and electron beam evaporation.

10. The preparation method for a phase change memory cell according to claim 8, wherein the phase change material is prepared by co-sputtering of monometallic targets or by sputtering of an alloy target.
